(19) United States
(12) Patent Application Publication
(10) Pub. No.: US 2026/0290707 A1
(43) Pub. Date: Sep. 24, 2026

(54) STRUCTURE COMPRISING TWO LAYERS OF DIFFERENT ELECTRICAL NATURE AND ITS PREPARATION METHOD

(71) Applicant: COMMISSARIAT A L'ENERGIE ATOMIQUE ET AUX ENERGIES ALTERNATIVES, Paris (FR)

(72) Inventor: Messaoud BEDJAOUI, Grenoble Cedex 09 (FR)

(73) Assignee: COMMISSARIAT A L'ENERGIE ATOMIQUE ET AUX ENERGIES ALTERNATIVES, Paris (FR)

(21) Appl. No.: 19/475,621

(22) PCT Filed: May 3, 2024
(86) PCT No.: PCT/FR2024/050582

§ 371 Date: Oct. 15, 2025

(30) Foreign Application Priority Data
May 4, 2023 (FR) FR2304489

(51) Int. Cl. H01G 4/33; H01G 4/01; H01G 4/08; H01G 4/10

(52) U.S. Cl. CPC H01G 4/33; H01G 4/085; H01G 4/105; H01G 4/01

(57) ABSTRACT

A structure comprises a substrate covered by a stack comprising a first layer and a second layer, the first layer being electrically conductive and comprising a first specific chemical element, the second layer being a dielectric layer comprising a second specific chemical element. The structure comprises a first transition zone between the first layer and the second layer. The first transition zone comprises the first specific chemical element and the second specific chemical element. Advantageously, the structure comprises a second transition zone. An assembly is formed by the first transition zone, the second layer, and the second transition zone.

### TECHNICAL FIELD

The invention relates to the field of micro- and nano-structures for micro- and nano-electronic and optronic devices.

More specifically, the invention relates to a structure comprising two layers of different electrical nature.

It also relates to a method for preparing a structure as defined above.

The invention has a use in particular in the manufacturing of high-density capacitors, for example of the MIM (for “Metal-Insulator-Metal”) type for devices such as digital memories, analog or digital converters or radiofrequency filters.

### Prior Art

The advent of connected and smart objects is currently the subject of research and in particular research on highly advanced and increasingly complex micro- and nano-electronic devices.

Besides the developments related to the architecture and to the “design” of the micro- and nano-electronic components allowing to satisfy highly advanced technological criteria and performance, research is being carried out to allow an ever-greater reduction in the size of these components.

The capacitors of the MIM type represent one of the indispensable components for such micro- and nano-electronic devices and are obtained, most often, by successive depositions of a first electric layer, a dielectric layer and a second electric layer.

Generally, such layers are deposited by atomic layer deposition (or “ALD”) or by plasma-enhanced ALD (called PEALD), allowing successive depositions of extremely thin and conformable layers, that is to say perfectly conforming to the surface of the substrate which is intended to support a stack of these layers.

However, manufacturing a capacitor of the MIM type is often likened to manufacturing a capacitor of the MOIM (for “Metal-Oxide-Insulator-Metal”), or even MOIOM (for “Metal-Oxide-Insulator-Oxide-Metal”), type as described in the application EP 3570307-A1 or in the patent U.S. Pat. No. 10,319,806-B2.

Indeed, an oxidation of the electric layers (or called “metal layers”) can occur in an unwanted and uncontrolled manner, thus introducing non-conductive oxide interface layers between the metal layer and the dielectric layer. These layers of oxide are not desirable in such structures since they are likely to modify the electrical response, or affect the electrical operation, of the capacitor of the MIM type.

Furthermore, the growth of the electric layers, which are generally made of a metal and/or a metal nitride, on a dielectric layer can suffer from a delay in growth, or even a lack of growth, due to the nature of the electric and dielectric layers used.

Given the above, the inventors have set the goal of overcoming the disadvantages of the prior art, in particular by proposing a structure comprising a stack of two layers of different electrical nature while avoiding the formation of oxide interface layers, thus allowing to obtain structures with good performance and avoiding the degradation thereof.

### DISCLOSURE OF THE INVENTION

The invention aims precisely to provide such a structure.

The object of the invention is therefore, firstly, a structure comprising a substrate covered by a stack comprising a first layer and a second layer, the first layer being electrically conductive (also called first electrode) and comprising a first specific chemical element, the second layer being a dielectric layer or an electrically insulating layer, the second layer comprising a second specific chemical element. The structure comprises a first transition zone between the first layer and the second layer. The first transition zone is in contact with the first layer and the second layer. In other words, no other material is present between the first layer and the first transition zone, nor between the second layer and the first transition zone.

The first transition zone comprises the first specific chemical element and the second specific chemical element but is devoid of oxygen.

It should be noted that the structure can comprise a stack successively comprising, starting from the substrate, the first layer then the second layer or a stack successively comprising, starting from the substrate, the second layer then the first layer, preference being given however to the stack successively comprising, starting from the substrate, the first layer then the second layer.

Furthermore, it is specified that the second layer can be a unitary dielectric layer, made of a single material, or can comprise several dielectric layers, in the form of an alternation of different unitary layers, to carry out microelectronic or optronic functionalities, preference being given however to a unitary layer.

The invention fundamentally differs from the prior art by the presence of the first transition zone which allows to guarantee a continuity of growth of the first layer and of the second layer of the structure, without degrading their intrinsic properties.

Indeed, the first transition zone allows both to finalize the growth of the first layer and to initiate the growth of the second layer, while having a role of barrier to the oxidation of the first layer. The first transition zone thus allows to avoid the formation of an oxide interface layer.

It is specified that, above and below, the term “growth” means that the second layer can be deposited and grow on the surface of the underlying first layer, so as to have a homogeneous desired thickness over this entire surface.

One of the properties of the first transition zone is related to its physicochemical affinity with the first layer and with the second layer, this transition zone being in contact with these layers. The composition of such a transition zone is characterized by a mixture comprising at least the first specific chemical element—which the first layer comprises—and at least the second specific chemical element—which the second layer comprises. For example, the first layer can have as a specific chemical element an element called “A” while the second layer can have as a specific chemical element an element called “B”. In this case the first transition zone is characterized by a composition called “AB”.

The first transition zone is therefore judiciously chosen and adjusted according to the desired nature of the first layer and of the second layer.

Preferably, the first transition zone is not a layer of metal oxide. In other words, it is preferred for the first specific element and the second specific element to not be oxygen.

According to the invention, the first specific chemical element is, preferably, nitrogen and the second specific chemical element is, preferably, a metal, with it being understood that the first layer is made of a metal nitride and the second layer is made of a metal oxide or made of a metal oxynitride.

Typically, the first layer, electrically conductive, is selected so as to have an electrical resistivity of less than 10⁻³ Ω·cm, for example between 10⁻⁶ Ω·cm and 10⁻³ Ω·cm, while the second layer, electrically insulating, is chosen so as to have an electrical resistivity greater than 10⁵ Ω·cm, for example between 10⁵ Ω·cm and 10¹⁸ Ω·cm. This first layer can be used as the first electrode while this second layer can be used as a dielectric layer in a capacitor of the MIM type.

For example, the first layer can be made of a titanium nitride, molybdenum nitride, tungsten nitride, tantalum nitride or niobium nitride or made of a mixture thereof and the second layer can be made of an oxide of silicon, aluminum, hafnium, zirconium, tantalum, lanthanum or titanium, made of a mixture thereof. The second layer can also be made of a silicon oxynitride.

In this case, the first transition zone is, advantageously, made of aluminum nitride, tantalum nitride, hafnium nitride, niobium nitride, titanium carbonitride or tantalum carbonitride.

According to the invention, the first transition zone has a thickness, preferably, of between 0.1 nm and 3 nm and, even better, equal to 0.5 nm.

It is specified that, above and below, the expressions “from . . . to . . . ” and “between . . . and . . . ” are equivalent and intend to mean that the limits are included.

By having a very small thickness, the first transition zone can be easily integrated into the construction and the preparation of micro- and nano-structures such as capacitors of the MIM type.

Moreover, the stack can further comprise a third electrically conductive layer (also called second electrode), the second layer being disposed between the first layer and the third layer. The stack thus relating, in this case, to a capacitor of the MIM type.

According to an alternative embodiment, the third layer can be in contact with the second layer.

According to another alternative embodiment, the structure comprises a second transition zone between the second layer and the third layer. In this case, the second transition zone is in contact with the second layer and the third layer. In other words, no other material is present between the second layer and the second transition zone, nor between the third layer and the second transition zone.

According to this other alternative embodiment, the third layer comprises a third specific chemical element. The second transition zone thus comprises the second specific chemical element and the third specific chemical element but is devoid of oxygen. The third specific chemical element can be identical to or different from the first specific chemical element. Preferably, the third specific chemical element is identical to the first specific chemical element.

The second transition zone thus ensures the continuity between the second layer and the third layer.

One of the properties of the second transition zone is related to its physicochemical affinity with the second layer and with the third layer, this second transition zone being in contact with these layers. The composition of this second transition zone is characterized by a mixture comprising at least the second specific chemical element 20—which the second layer comprises—and at least the third specific chemical element—which the third layer comprises. For example, for a second layer having as a specific chemical element an element called “B” and a third layer having as a specific chemical element an element called “A′”, the second transition zone is characterized by a composition called “BA′”.

The second transition zone is therefore judiciously chosen and adjusted according to the desired nature of the second layer and of the third layer.

Preferably, the second transition zone is not a layer of metal. In other words, it is preferred for the third specific element and the second specific element to not be oxygen.

As mentioned above, the third specific chemical element is, preferably, identical to the first specific chemical element. Thus, the third specific chemical element can be nitrogen, with it being understood that the third layer is made of a metal nitride.

The third layer is also chosen so as to have an electrical resistivity being of less than 10⁻³ Ω·cm, for example between 10⁻⁶ Ω·cm and 10⁻³ Ω·cm. This third layer can be used as a second electrode in a capacitor of the MIM type.

This third layer can be identical to or different from the first layer, preferably identical, and can thus be made of a titanium nitride, molybdenum nitride, tungsten nitride, tantalum nitride or niobium nitride or made of a mixture thereof.

In this case, the second transition zone is, advantageously, made of aluminum nitride, tantalum nitride, hafnium nitride, niobium nitride, titanium carbonitride or tantalum carbonitride.

Preferably, the structure comprises one of the stacks as described in the following table I:

TABLE I

| First layer | First transition zone | Second layer |
|---|---|---|
| TiN | AlN | Al₂O₃ |
| TiN | AlN | Al₂O₃, TiO₂ |
| TiN | AlN | Al₂O₃, ZrO₂ |
| TiN | HfN | HfO₂ |
| TiN | HfN | HfZnO |
| TiN | TiCN | TiO₂ |
| TaN | TaCN | Ta₂O₅ |
| TaN | TaN | Ta₂O₅ |
| TaN | TaN | Ta₂O₅, Al₂O₃ |
| NbN | NbN | Nb₂O₅ |
| NbN | NbN | NbZnO |
| WN | AlN | Al₂O₃ |

The stacks described above can further comprise a second transition zone then a third layer. Preferably, the second transition zone is identical to the first transition zone. The third layer is, preferably, identical to the first layer.

The second transition zone has a thickness, preferably, of between 0.1 nm and 3 nm and, even better, equal to 0.5 nm.

Like for the first transition zone, this second transition zone, by having an extremely small thickness, can be easily integrated into the construction and the preparation of micro- and nano-structures, such as capacitors of the MIM type.

Furthermore, according to the invention, the substrate of the structure can have a flat surface—that is to say in two dimensions—or a microstructured surface—that is to say in three dimensions.

It is specified that, above and below, “microstructured surface” means a surface comprising pores or vias, for example having an elongated shape, which allows in particular to increase the specific surface area of the substrate—that is to say the surface area of the substrate intended to be covered by the stack comprising the first layer, the second layer and optionally the third layer—relative to a flat surface.

Thus, a microstructured surface can have a more or less large aspect ratio, this aspect ratio corresponding to the ratio of the longitudinal dimension to the transverse dimension of the pores or of the vias. Thus, the higher the aspect ratio, the greater the specific surface area of the substrate. For example, an aspect ratio greater than 20 is possible.

The substrate can also comprise microelectronic components.

The substrate can be made of silicon, made of metal nitride or made of a material based on a metal oxide such as alumina, or made of any other suitable material.

The structure as previously described can be prepared by a method which comprises at least the following successive steps:
a) depositing, preferably by ALD, one of the first layer or the second layer on the substrate;
b) depositing, preferably by ALD, the other of the first layer or the second layer;
   the method being characterized in that it comprises a substep of forming the first transition zone at the end of step a) or at the beginning of step b).

It is possible to deposit the first layer then the second layer, or vice versa. Preferably, steps a) and b) are carried out by the technique of ALD deposition under vacuum (from several mTorr to several Torr; or between approximately 0.1 Pa and several hundred Pa, for example 300 Pa) which allows in particular to obtain very conformable layers having a very high purity and very small thickness.

The depositions via ALD of step a) and of step b) can be implemented at a temperature between 200° C. and 450° C., for example at 400° C. for step a) and 330° C. for step b).

The sequence of steps a) and b) is typically carried out without breaking the vacuum, which allows in particular to avoid the formation of oxide interface layers between the first layer and the second layer.

The formation of the first transition zone is characterized in that it is carried out in a single step, either with the deposition of one of the first layer or the second layer—in the case that it is carried out at the end of step a)—or with the deposition of the other of the first layer or the second layer—in the case that it is carried out at the beginning of step b)—thus allowing to control the composition and the thickness of the various layers and of the first transition zone of the structure.

“A single step” means that the formation of the first transition zone is carried out under the same temperature and pressure conditions as the deposition of the first layer or as the deposition of the second layer.

The fact that the formation of the first transition zone can be judiciously adapted either at the end of step a) or at the beginning of step b) allows in particular to prepare several structures in parallel.

It is recalled that the principle of deposition by ALD lies in introducing at least two reactive species, called “precursors”, into an ALD chamber, then circulating them alternately on the surface of a material.

The choice of the precursors ultimately depends on the desired nature of the layer to be deposited or of the transition zone to be formed.

In the context of the invention, the substep of forming the first transition zone can be carried out by ALD by alternately introducing and circulating a first pair of precursors to form the first transition zone, characterized in that one of the precursors of the first pair of precursors comprises the first specific chemical element and the other precursor of this first pair comprises the second specific chemical element.

According to a first specific embodiment of the invention, the first layer deposited is made of titanium nitride (TiN) by using, for example, as precursors titanium tetrachloride (TiCl₄), tetrakis(dimethylamino) titanium (TDMAT) or even tetrakis(diethylamino) titanium (TDEAT), all being coupled with ammonia.

According to this first specific embodiment, a second layer made of alumina (Al₂O₃) can be deposited, for example, by using as a precursor trimethylaluminum (TMA) coupled with water vapor, in which case the first transition zone can advantageously be made of aluminum nitride (AlN), by using, for example, as the first pair of precursors TMA coupled with ammonia.

Still according to this first specific embodiment, the second layer deposited can also be made of a mixture comprising aluminum oxide and titanium oxide (Al₂O₃, TiO₂) by using, for example, as precursors TMA coupled with water for Al₂O₃ and TiCl₄ coupled with water for TiO₂ or the second layer can be made of a mixture comprising aluminum oxide and zirconium oxide (Al₂O₃, ZrO₂) by using, for example, as precursors TMA coupled with water for Al₂O₃ and zirconium tetrachloride (ZrCl₄) coupled with water for ZrO₂, in which case the first transition zone can advantageously be made of AlN by using, for example, as the first pair of precursors TMA coupled with an ammonia plasma.

Still according to this first specific embodiment, the second layer deposited can be made of hafnium oxide (HfO₂) by using, for example, as a precursor hafnium tetrachloride (HfCl₄) coupled with water or the second layer can be made of HfZnO by using, for example, as precursors HfCl₄ and diethylzinc (DEZ) coupled with water, in which case the first transition zone can advantageously be made of hafnium nitride (HfN) by using, for example, as the first pair precursors HfCl₄ coupled with an ammonia plasma or coupled with an H₂N₂ plasma.

Still according to this first specific embodiment, a second layer made of titanium oxide (TiO₂) can be deposited, for example, by using TiCl₄ or TOMAT as precursors, these two precursors being coupled with water, in which case the first transition zone can advantageously be made of titanium carbonitride (TiCN), by using, for example, as the first pair of precursors TDMAT coupled with an ammonia plasma or coupled with an H₂N₂ plasma.

According to a second specific embodiment of the invention, the first layer deposited is made of tantalum nitride (TaN) by using, for example, as precursors tris(diethylamido) (tert-butylimido) tantalum (TBTDET) coupled with ammonia.

According to this second specific embodiment, the second layer deposited can be made of tantalum oxide (Ta₂O₅) by using, for example, as precursors TBTDET coupled with an O₂ plasma, in which case the first transition zone can be advantageously made of tantalum carbonitride (TaCN) by using, for example, as the first pair of precursors TBTDET coupled with an ammonia plasma or coupled with an H₂N₂ plasma.

Finally, according to a third specific embodiment of the invention, the first layer deposited is made of tungsten nitride (WN) by using, for example, as precursors tungsten pentachloride or tungsten hexachloride coupled with ammonia.

According to this third specific embodiment, the second layer deposited can be made of Al₂O₃ by using, for example, as precursors TMA coupled with water vapor, in which case the first transition zone can be advantageously made of AlN by using, for example, as the first pair of precursors TMA coupled with ammonia.

According to the invention, steps a) and b) can also be carried out successively by ALD in the same ALD chamber, by using different precursors during steps a) and b). In this case, the formation of the first transition zone is carried out only during the changing of the precursors used in step b) to deposit the other of the first layer or the second layer. This allows in particular to eliminate a step of changing ALD chamber between steps a) and b) and also allows to eliminate the use of specific precursors for the formation of the first transition zone.

The introduction and alternating circulation of each of the precursors are followed by a time, called waiting time, before carrying out a purge thereof.

The waiting time represents the residence time of the precursors on the surface of the substrate or, if applicable, on the surface of the underlying layer. It is directly proportional to the value of the aspect ratio of the substrate. The waiting time allows to make the precursors diffuse and react in an optimal manner, in particular in the complex structures comprising for example a microstructured surface with a high aspect ratio.

Typically, the waiting time can be set to between 15 seconds and 100 seconds, preferably set to 30 seconds.

As for the purge, it is generally implemented for a duration that can go from 5 seconds to 40 seconds, to eliminate the excess precursors and the possible undesired byproducts, obtained during a reaction between the precursors.

The introduction and alternating circulation can be repeated a certain number of times until a desired thickness is obtained. For example, in the context of the invention, the thickness of the first layer and the thickness of the second layer are typically controlled between 1 nm and 50 nm (for example equal to 10 nm for the first layer and equal to 19 nm for the second layer), while the thickness of the first transition zone is typically controlled between 0.1 nm and 3 nm and, preferably, equal to 0.5 nm, by adjusting the number of repetitions of introduction and circulation of each of the precursors.

According to a specific embodiment of the invention, the method can further comprise a step c) during which the third layer is deposited, preferably by ALD, on the second layer, the method being characterized in that it comprises a substep of forming the second transition zone at the end of step b) or at the beginning of step c), with it being understood that, in this case, the first layer is deposited during step a) and the second layer is deposited during step b).

This embodiment is particularly advantageous in the context of the preparation of capacitors of the MIM type for example.

The deposition by ALD of step c) can be implemented at a temperature between 200° C. and 450° C., for example at a temperature equal to 400° C.

The sequence of steps b) and c) is also carried out without breaking the vacuum, for the same reasons as explained above.

The formation of the second transition zone is characterized in that it is carried out in a single step either with the deposition of the second layer—in the case that it is carried out at the end of step b)—or with the deposition of the third layer—in the case that it is carried out at the beginning of step c)—thus allowing to control the composition and the thickness of the various layers and of the second transition zone of the structure.

“A single step” means that the formation of the second transition zone takes place under the same temperature and pressure conditions as the deposition of the second layer or as the deposition of the third layer.

The fact that the formation of the second transition zone can be judiciously adapted either at the end of step b) or at the beginning of step c) allows to prepare several structures in parallel and, in particular, in this case to prepare several capacitors of the MIM type in parallel.

According to the invention, the substep of forming the second transition zone can be carried out by ALD by alternately introducing and circulating a second pair of precursors for the formation of the second transition zone, characterized in that one of the precursors of the second pair of precursors comprises the second specific chemical element and the other precursor of this second pair comprises the third specific chemical element.

Here again, the choice of the precursors depends on the desired nature of the second layer, of the third layer, and of the second transition zone.

A person skilled in the art is perfectly capable of adapting the choice of the precursors according to the nature of the layers to be deposited and of the transition zones to be formed.

According to the invention, steps a), b) and c) can also be carried out successively by ALD in the same ALD chamber, by using different precursors during steps a) and b) and during steps b) and c). In this case, the formation of the first transition zone is carried out only during the changing of the precursors used in step b) to deposit the second layer and the formation of the second transition zone is carried out only during the changing of the precursors used in step c) to deposit the third layer. This allows in particular to eliminate a step of changing ALD chamber between steps a) and b) and between steps b) and c) and also allows to eliminate the use of specific precursors for the formation of the first transition zone and for the formation of the second transition zone.

It should be noted that the first layer, the second layer and/or the third layer can be structured, and thus have specific patterns, according to the conventional techniques of the prior art, for example by etching.

Alternatively to the deposition by ALD, steps a), b) and c) and the substeps of forming the first transition zone and the second transition zone can also be implemented by a plasma-enhanced ALD method (also called PEALD for “Plasma-Enhanced Atomic Layer Deposition”), by a spatial ALD method (also called SALD for “Spatial Atomic Layer Deposition”) or by an ALD method at atmospheric pressure.

Other alternatives can be implemented, in particular for the deposition of the first electrode and/or the deposition of the second electrode, such as deposition techniques adapted to thin layers, such as physical vapor deposition (or PVD) or chemical vapor deposition (or CVD).

A person skilled in the art is perfectly capable of choosing the most suitable deposition method, in particular according to the surface of the substrate used (flat or microstructured).

The invention is particularly advantageous for preparing MIM structures formed from ultrathin layers.

Nevertheless, the invention can be implemented for structures having layers with thicknesses that can go up to 100 nm.

Other features and advantages of the invention will be clear from the following additional description.

It goes without saying that this additional description is only given as an illustration of the object of the invention and must in no case be interpreted as a limitation of this object.

### BRIEF DESCRIPTION OF THE DRAWINGS

FIG. 1 shows a substrate 10 having a flat surface covered by a first electrode 20.

FIG. 2 shows a structure comprising the substrate 10, the surface of which is covered by a stack comprising the first electrode 20 and an assembly 300 formed successively by a first transition zone, a dielectric layer and a second transition zone (for reasons of readability, the detail of the assembly 300 is not shown in this drawing).

FIG. 3 shows the detail of the assembly 300 formed successively by the first transition zone 2030, the dielectric layer 30 and the second transition zone 3040.

FIG. 4 shows a structure S1 of the MIM type, obtained according to a specific embodiment of the invention, comprising the substrate 10, the surface of which is covered by a stack successively comprising the first electrode 20, the assembly 300 and a second electrode 40 (for reasons of readability, the detail of the assembly 300 is not shown in this drawing).

FIG. 5 shows (left part) a structure S2 of the MIM type, obtained according to another specific embodiment of the invention, comprising the substrate 10, the surface of which is covered by a stack successively comprising an assembly 200, an assembly 301 and the second electrode 40; the detail of the assembly 200, formed successively by the first electrode 20 and by the first transition zone 2030 and the detail of the assembly 301, formed successively by the dielectric layer 30 and by the second transition zone 3040, are shown on the right part of this drawing.

FIG. 6 shows (left part) a structure S3 of the MIM type, obtained according to another specific embodiment of the invention, comprising the substrate 10, the surface of which is covered by a stack successively comprising the first electrode 20, an assembly 302 and an assembly 400; the detail of the assembly 302, formed successively by the first transition zone 2030 and by the dielectric layer 30 and the detail of the assembly 400, formed successively by the second transition zone 3040 and by the second electrode 40, are shown on the right part of this drawing.

FIG. 7 shows (left part) a structure S4 of the MIM type, obtained according to another specific embodiment of the invention, comprising the substrate 10, the surface of which is covered by a stack successively comprising the assembly 200, the dielectric layer 30 and the assembly 400; the detail of the assembly 200, formed by the first electrode 20 and by the first transition zone 2030 and the detail of the assembly 400, formed by the second transition zone 3040 and by the second electrode 40, are shown on the right part of this drawing.

FIG. 8 shows a structure of the MIM type, obtained according to another specific embodiment of the invention, comprising a substrate 100, the surface of which is microstructured and is covered by a stack successively comprising the first electrode 20, the assembly 300 and the second electrode 40 (for reasons of readability, the detail of the assembly 300 is not shown in this drawing).

It should be noted that the drawings described above are schematic representations, the relative dimensions and proportions of the substrates 10 and 100, of the first electrode 20, of the first transition zone 2030, of the dielectric layer 30, of the second transition zone 3040 and of the second electrode 40 of which are not representative of those likely to be presented in a real situation, for reasons of readability.

### DETAILED DISCLOSURE OF SPECIFIC EMBODIMENTS

### Example 1: Preparation of a First Structure S1

1.1—Deposition of the First Layer of an Electrically Conductive Nature: A substrate 10 is placed in a first ALD chamber under vacuum dedicated to the depositions of electrically conductive layers, called electric layers or electrodes.

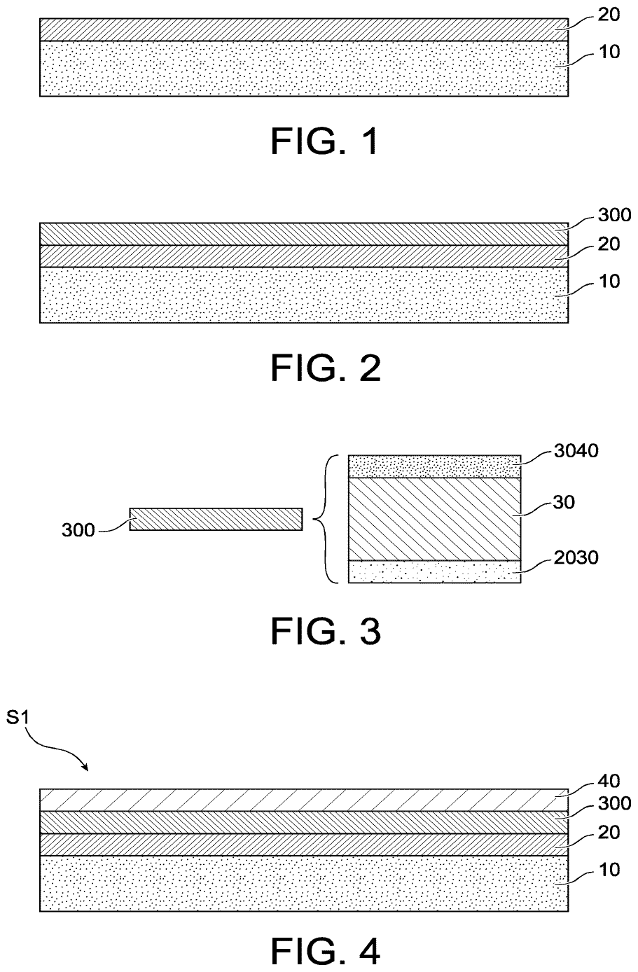

The substrate 10 is made of silicon with an electrical insulation made of silicon oxide. It has a flat surface (FIG. 1).

A deposition by ALD is implemented at a temperature equal to 400° C. by carrying out 200 times the following step cycle:
injection of TiCl₄ for an injection duration equal to 2 seconds;
circulation of the TiCl₄ on the surface of the substrate 10, while observing a waiting time equal to 30 seconds;
purge for 40 seconds of the excess TiCl₄; then
injection of ammonia (NH₃);
circulation of the NH₃ on the surface of the substrate 10;
purge of the excess NH₃ as well as of the possible byproducts obtained during a reaction between the TiCl₄ and the NH₃.

The injection duration, the waiting and purge time for the NH₃ are the same as those applied for the TiCl₄.

Thus, the first electrode 20 made of TiN, having a thickness of 10 nm, is deposited over the entire surface of the substrate 10, as illustrated in FIG. 1.

### 1.2—Formation of the First Transition Zone, Deposition of the Second Layer of an Electrically Insulating Nature and Formation of the Second Transition Zone:

The assembly formed by the substrate 10 and the first electrode 20 made of TiN, obtained in point 1.1 above, is moved to a second ALD chamber under vacuum, at 330° C., this time dedicated to the depositions of layers of an electrically insulating nature, called dielectric layers.

The movement is carried out without passage through air—that is to say that the assembly remains under vacuum—which allows to avoid the formation of an additional oxide interface layer on the surface of the electrode 20 made of TiN.

### 1.2.1—Formation of the First Transition Zone

The first transition zone is formed by ALD deposition by alternately introducing and circulating TMA and NH₃ on the surface of the electrode 20.

The TMA is introduced for 1 second then a purge thereof is carried out for 5 seconds while the NH₃ is introduced for 5 seconds then a purge of the latter and of any by-products, obtained during a reaction between the TMA and the NH₃, is carried out for 10 seconds.

The alternating introduction and circulation of the TMA and of the NH₃ is repeated 35 times, while respecting the injection and purge times mentioned above, while observing a waiting time of 30 seconds.

Thus, the first transition zone 2030 made of AlN is formed over the entire surface of the first electrode 20 and has a thickness of 0.5 nm.

### 1.2.2—Deposition of the Dielectric Layer

While remaining in the second ALD chamber, the second layer of an electrically insulating nature 30, called dielectric layer, is then deposited by ALD.

Here, TMA and water vapor are introduced and circulate, alternately, on the surface of the first transition zone 2030 obtained above.

The TMA and the water vapor are each introduced for 0.1 seconds then, after each introduction, a purge is carried out for 5 seconds after having observed a waiting time of 30 seconds.

The alternating introduction and circulation of the TMA and of the water vapor are repeated 200 times, allowing to obtain the dielectric layer 30 made of Al₂O₃ having a thickness of 19 nm, over the entire surface of the first transition zone 2030.

### 1.2.3—Formation of the Second Transition Zone

Finally, the second transition zone 3040 is formed on the surface of the dielectric layer 30 in the second chamber ALD.

The formation of the second transition zone 3040 is implemented according to the same ways as those described in point 1.2.1 above.

The second transition zone 3040 made of Al having a thickness of 0.5 nm is thus formed over the entire surface of the dielectric layer 30.

A structure which thus comprises a stack successively comprising the first electrode 20 and an assembly 300, successively formed by the first transition zone 2030, the dielectric layer 30 and the second transition zone 3040, is obtained and is shown in FIG. 2.

For reasons of legibility, the detail of the assembly 300 is not shown in FIG. 2 but is shown in FIG. 3.

### 1.3—Deposition of the Third Layer of an Electrically Conductive Nature:

The structure obtained in point 1.2 above is moved to a third ALD chamber under vacuum, dedicated to the depositions of electrodes.

The movement from the second ALD chamber to the third ALD chamber is, here too, carried out without passage through air, to avoid any formation of an oxide interface layer on the surface of the assembly 300.

The second electrode 40 made of TiN is deposited on the surface of the assembly 300 by implementing the same cycle of steps as that described in point 1.1.

The second electrode 40 thus deposited has a thickness of 10 nm.

A structure S1 of the MIM type is thus obtained and is shown in FIG. 4.

### Example 2: Preparation of a Second Structure S2

A second structure S2 of the MIM type is prepared according to another specific embodiment of the invention.

The preparation of the second structure S2 comprises the following successive steps and substeps:
a) i) depositing the first electrode 20 made of TiN;
   ii) forming the first transition zone 2030 made of AlN;
b) i) depositing the dielectric layer 30 made of Al₂O₃;
   ii) forming the second transition zone 3040 made of AlN;
c) depositing the second electrode 40 made of TiN.

The above steps and substeps are all implemented according to the same ways as those described in example 1, except that the first transition zone is, here, formed at the end of step a)—corresponding to the deposition of the first electrode 20—that is to say that it is formed in the first ALD chamber under vacuum, dedicated to the depositions of electrodes, at a temperature of 400° C.

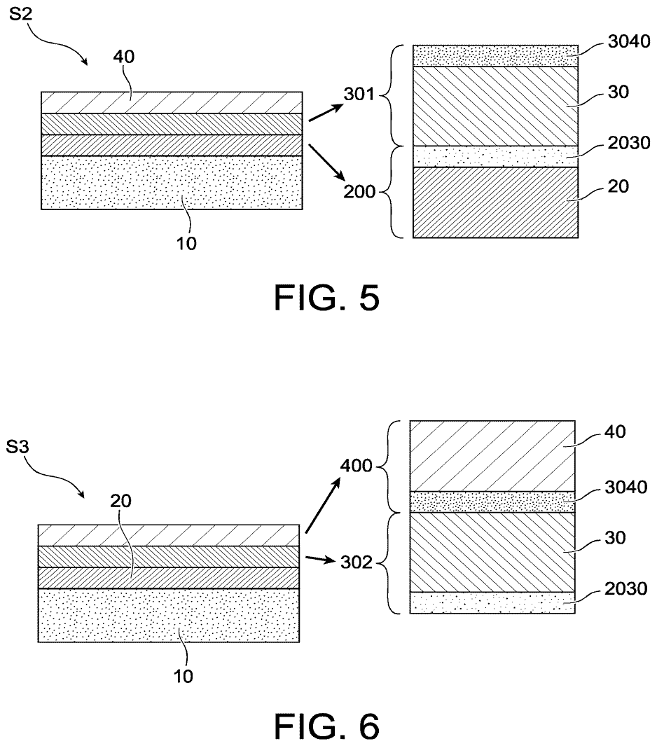

A structure S2 of the MIM type is thus obtained and shown in FIG. 5 (left part). This structure comprises a substrate 10 covered by a stack successively comprising:
an assembly 200 which successively comprises the first electrode 20 made of TiN and the first transition zone 2030 made of AlN;
an assembly 301 which successively comprises the dielectric layer 30 made of Al₂O₃ and the second transition zone 3040 made of AlN; then
the second electrode 40 made of TiN.
   The detail of this stack is shown in FIG. 5 (right part).

### Example 3: Preparation of a Third Structure S3

A third structure S3 of the MIM type is prepared according to another specific embodiment of the invention.

The preparation of the third structure S3 comprises the following successive steps and substeps:
a) depositing the first electrode 20 made of TiN;
b) i) forming the first transition zone 2030 made of AlN;
   ii) depositing the dielectric layer 30 made of Al₂O₃;
c) i) forming the second transition zone 3040 made of AlN;
   ii) depositing the second electrode 40 made of TiN.

The above steps and substeps are all implemented according to the same ways as those described in example 1, except that the second transition zone is, here, formed at the beginning of step c)—corresponding to the deposition of the second electrode 40—that is to say that it is formed in the third ALD chamber under vacuum, dedicated to the depositions of electrodes, at a temperature of 400° C.

A third structure S3 of the MIM type is thus obtained and shown in FIG. 6 (left part). This structure comprises a substrate 10 covered by a stack successively comprising:
the first electrode 20 made of TiN;
an assembly 302 which successively comprises the first transition zone 2030 made of AlN and the dielectric layer 30 made of Al₂O₃; then
an assembly 400 which successively comprises the second transition zone 3040 made of AlN and the second electrode 40 made of TiN.

The detail of this stack is shown in FIG. 6 (right part).

### Example 4: Preparation of a Fourth Structure S4

A fourth structure S4 of the MIM type is prepared according to another specific embodiment of the invention.

The preparation of the fourth structure S4 comprises the following successive steps and substeps:
a) i) depositing the first electrode 20 made of TiN;
   ii) forming the first transition zone 2030 made of AlN;
b) depositing the dielectric layer 30 made of Al₂O₃;
c) i) forming the second transition zone 3040 made of AlN;
   ii) depositing the second electrode 40 made of TiN.

The above steps and substeps are all implemented according to the same ways as those described in example 1, except that the first transition zone 2030 is formed at the end of step a)—corresponding to the deposition of the first electrode 20—and the second transition zone 3040 is formed at the beginning of step c)—corresponding to the deposition of the second electrode 40.

In other words, the first transition zone 2030 is formed in the first ALD chamber and the second transition zone is formed in the third ALD chamber, that is to say that the first transition zone 2030 and the second transition zone 3040 are both formed in ALD chambers under vacuum, dedicated to the depositions of electrodes, at a temperature of 400° C.

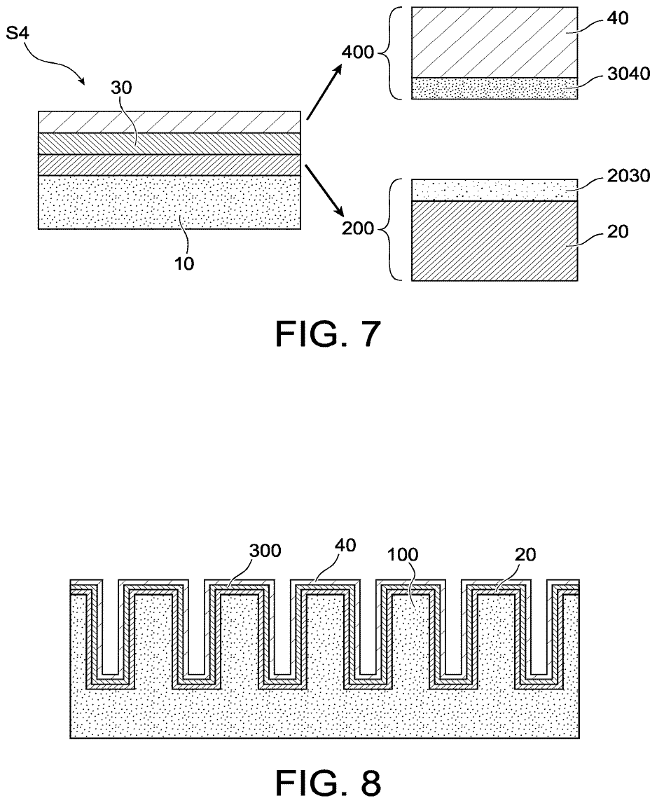

A structure S4 of the MIM type is thus obtained and shown in FIG. 7 (left part). This structure comprises a substrate 10 covered by a stack successively comprising:
the assembly 200 which successively comprises the first electrode 20 made of TiN and the first transition zone 2030 made of AlN;
the dielectric layer 30 made of Al₂O₃; then
the assembly 400 which successively comprises the second transition zone 3040 made of AlN and the second electrode 40 made of TiN.

The detail of this stack is shown in FIG. 7 (right part).

In the above examples, the substrate is a substrate having a flat surface. However, as shown in FIG. 8, the method for preparing a structure such as a capacitor of the MIM type could be applied to a substrate 100 having a microstructured surface. The various elements (first electrode 20, assembly 300 and second electrode 40) are then successively deposited on the substrate 100.

1. A structure, comprising:
a substrate covered by a stack comprising a first layer and a second layer, the first layer being electrically conductive and comprising a first specific chemical element, the second layer being a dielectric layer or an electrically insulating layer, the second layer comprising a second specific chemical element,
wherein the structure comprises a first transition zone between the first layer and the second layer, and the first transition zone comprises the first specific chemical element and the second specific chemical element,
the first specific chemical element is nitrogen and the second specific chemical element is a metal,
the first layer being is made of a metal nitride and the second layer is made of a metal oxide or made of a metal oxynitride,
the first transition zone is in contact with the first layer, and
the second layer has a thickness between 0.1 nm and 3 nm and is devoid of oxygen.

2. The structure according to claim 1, wherein the first layer is made of titanium nitride, molybdenum nitride, tungsten nitride, tantalum nitride, or niobium nitride, or a mixture thereof, and
the second layer is made of an oxide of silicon, aluminum, hafnium, zirconia, tantalum, lanthanum, or titanium, a mixture thereof, or made of a silicon oxynitride.

3. The structure according to claim 2, wherein the first transition zone is made of aluminum nitride, tantalum nitride, hafnium nitride, niobium nitride, titanium carbonitride, or tantalum carbonitride.

4. The structure according to claim 1, wherein the first transition zone has a thickness equal to 0.5 nm.

5. The structure according to claim 1, wherein the stack comprises an electrically conductive third layer, and the second layer being is disposed between the first layer and the third layer.

6. The structure according to claim 5, wherein the third layer comprises a third specific chemical element,
wherein the structure further comprises a second transition zone between the second layer and the third layer,
the second transition zone comprises the second specific chemical element and the third specific chemical element, the third specific chemical element being identical to the first specific chemical element, and
the second transition zone is in contact with the second layer and the third layer and is devoid of oxygen.

7. The structure according to claim 1, wherein the substrate has a microstructured surface.

8. A method for preparing the structure according to claim 1, the method comprising:
(a) depositing one of the first layer or the second layer on the substrate; and
(b) depositing the other of the first layer or the second layer,
wherein the method further comprises forming the first transition zone at an end of step (a) or at a beginning of step (b).

9. The method according to claim 8, wherein the step of forming the first transition zone is performed by ALD by alternately introducing and circulating a first pair of precursors to form the first transition zone, and
one of the precursors of the first pair of precursors comprises the first specific chemical element and the other precursor of the first pair comprises the second specific chemical element.

10. The method according to claim 8, wherein the steps (a) and (b) are successively performed by ALD in a same ALD chamber, by using different precursors during steps (a) and (b), and
wherein the formation of the first transition zone is performed only during the changing of the precursors used in step (b) to deposit the other of the first layer or the second layer.

11. The method according to claim 8, wherein the first layer is deposited during step (a) and the second layer is deposited during step (b),
the method further comprises a step (c) during which the third layer is deposited on the second layer, and
the method further comprises forming the second transition zone at the end of step (b) or at the beginning of step (c).

12. The method according to claim 11, wherein the step of forming the second transition zone is performed by ALD by alternately introducing and circulating a second pair of precursors for forming the second transition zone, and
one of the precursors of the second pair of precursors comprises the second specific chemical element and the other precursor of this second pair comprises the third specific chemical element.

13. The method according to claim 11, wherein the steps (a), (b), and (c) are successively performed by ALD in a same ALD chamber, by using different precursors during steps (a) and (b) and during steps (b) and (c), and
wherein the formation of the first transition zone is performed only during the changing of the precursors used in step (b) to deposit the second layer and the formation of the second transition zone is performed only during the changing of the precursors used in step (c) to deposit the third layer.
